(19) United States
(12) Patent Application Publication
(10) Pub. No.: US 2009/0188710 A1
(43) Pub. Date: Jul. 30, 2009

(54) SYSTEM AND METHOD FOR FORMING FILLED VIAS AND PLATED THROUGH HOLES

(75) Inventor: David D. Senk, San Ramon, CA (US)

Correspondence Address: Patent Capital Group - Cisco, 6119 McCommas, Dallas, TX, 75214, US

(73) Assignee: CISCO TECHNOLOGY, INC., San Jose, CA (US)

(21) Appl. No.: 12/022,157

(22) Filed: Jan. 30, 2008

(51) Int. Cl. H05K 1/11; H05K 3/42

(52) U.S. Cl. 174/262; 29/852

(57) ABSTRACT

Methods and apparatus for creating a filled, backdrilled plated through hole in a printed circuit board are disclosed. According to one aspect of the present invention, a method includes defining a hole in a printed circuit board panel. The hole has a first surface, and includes at least a first portion and a second portion. The method also includes plating the first surface with a conductive material, to create a plated surface, and removing at least a first area of the plated surface. The first area of the plated surface is associated with the second portion, and removing the first area of the plated surface includes expanding a size of the hole associated with the second portion. Finally, the method includes filling the hole with a non-conductive material.

### BACKGROUND OF THE INVENTION

The present invention relates generally to the design and manufacture of printed circuit boards. More particularly, the present invention relates to filling backdrilled through holes in a printed wiring board (PWB) with a non-conductive material such that that higher density routing may be permitted.

Printed circuit boards or PWBs are used in the formation of a wide variety of electrical devices. Typically, printed circuit boards include multiple layers of conductors, e.g., copper conductors, which are interconnected by metallized holes. Each metallized hole has plating that connects the layers of conductors exposed in the metallized hole to each other. For example, if three layers of a printed circuit board have conductors or traces through which the metallized hole passes, the three layers are interconnected. If a lead of an electrical component is inserted through a metallized hole, the plating in the metallized hole connects the layers of conductors exposed in the metallized hole to each other and to the electrical component.

As the circuit density on printed circuit boards increases, the need to efficiently utilize space on printed circuit boards is also increasing. In general, there are spacing requirements which substantially dictate where traces, vias, and through holes may be placed. Such spacing requirements often make it difficult to efficiently utilize space on printed circuit boards. By way of example, backdrilling is relatively difficult to safely employ in high density areas on a printed circuit board, as there is a risk of exposing traces routed near or between backdrilled holes, as well as a risk of violating minimum metal-to-exposed edge spacing requirements associated with the printed circuit board.

### BRIEF DESCRIPTION OF THE DRAWINGS

The present invention will be readily understood by the following detailed description in conjunction with the accompanying drawings, wherein like reference numerals designate like structural elements, and in which:

FIG. 1 is a process flow diagram which illustrates one process of creating backdrilled, filled printed wiring board (PWB) vias or plated through holes in accordance with an embodiment of the present invention.

FIG. 2A is a diagrammatic cross-sectional side-view representation of a panel in which a backdrilled via is formed in accordance with an embodiment of the present invention.

FIG. 2B is a diagrammatic cross-sectional side-view representation of a panel, e.g., panel 200 of FIG. 2A, in which a backdrilled, filled via is formed in accordance with an embodiment of the present invention.

FIG. 3A is a diagrammatic cross-sectional side view representation of a panel in which a through hole is formed in accordance with an embodiment of the present invention.

FIG. 3B is a diagrammatic cross-sectional side view representation of a panel, e.g., panel 300 of FIG. 3A, after a hole, e.g., hole 336 of FIG. 3A, has been plated in accordance with an embodiment of the present invention.

FIG. 3C is a diagrammatic cross-sectional side view representation of a panel, e.g., panel 300 of FIG. 3A, after a plated hole, e.g., hole 336 of FIG. 3A, has been partially backdrilled in accordance with an embodiment of the present invention.

FIG. 3D is a diagrammatic cross-sectional side view representation of a panel, e.g., panel 300 of FIG. 3A, after an epoxy filling process has occurred in accordance with an embodiment of the present invention.

FIG. 3E is a diagrammatic cross-sectional side view representation of a panel, e.g., panel 300 of FIG. 3A, after a planarization process and an additional plating process have occurred in accordance with an embodiment of the present invention.

### DESCRIPTION OF EXAMPLE EMBODIMENTS

### General Overview

In one embodiment, a method includes defining a hole in a printed circuit board panel. The hole has a first surface, and includes at least a first portion and a second portion. The method also includes plating the first surface with a conductive material, to create a plated surface, and removing at least a first area of the plated surface. The first area of the plated surface is associated with the second portion, and removing the first area of the plated surface includes expanding a size of the hole associated with the second portion. Finally, the method includes filling the hole with a non-conductive material.

### Description

The ability to efficiently utilize space associated with a printed circuit board or a printed wiring board (PWB) substantially without compromising the performance associated with the printed circuit board, enhances the utility of the printed circuit board. As space is typically at a premium on printed circuit boards, the efficient utilization of space is often critical.

By backdrilling vias and plated through holes in a printed circuit board or a PWB that includes at least one trace or wire, and then filling the vias and plated through holes with a non-conductive material such as epoxy, the likelihood that metal traces exposed in backdrilled areas may adversely affect the operation of the printed circuit board may be effectively eliminated. Further, backdrilling vias and plated through holes, and filling the vias and plated through holes with a non-conductive material, also effectively eliminates issues associated with relatively low metal-to-exposed edge dimensions in backdrilled areas. That is, the use of a non-conductive material such as epoxy substantially eliminates the effects associated with exposed metal traces and relatively low metal-to-exposed edge dimensions of backdrilled areas associated with vias and plated through holes. Hence, relatively high density circuit routing between backdrilled holes, e.g., holes in relatively high pin density areas of a circuit board such as beneath a ball grid array (BGA), may be possible. In one embodiment, 2-track routing between backdrilled vias that are located under approximately one millimeter (mm) BGAs may be permitted.

Additionally, backdrilling and filling plated or metallized through holes of a printed circuit board permits photo-defined plane layer anti-pads to substantially be eliminated from back-drilled areas of the printed circuit board. As a result, the amount of copper coverage associated with the printed circuit board may be increased, thereby improving the signal integrity associated with the printed circuit board.

In one embodiment, backdrilling through holes and filling the backdrilled through holes with a non-conductive material permits a higher routing density between the backdrilled holes. By way of example, a 2-track routing density may be permitted between backdrilled holes beneath an approximately 1 mm BGA as a result of epoxy filling effectively eliminating the risk of exposed copper or too small of a hole-to-edge metal feature spacing in the backdrilled areas of the holes and, hence, substantially reducing a drilled edge-to-metal feature minimum spacing requirement to the point that 2-track routing is possible.

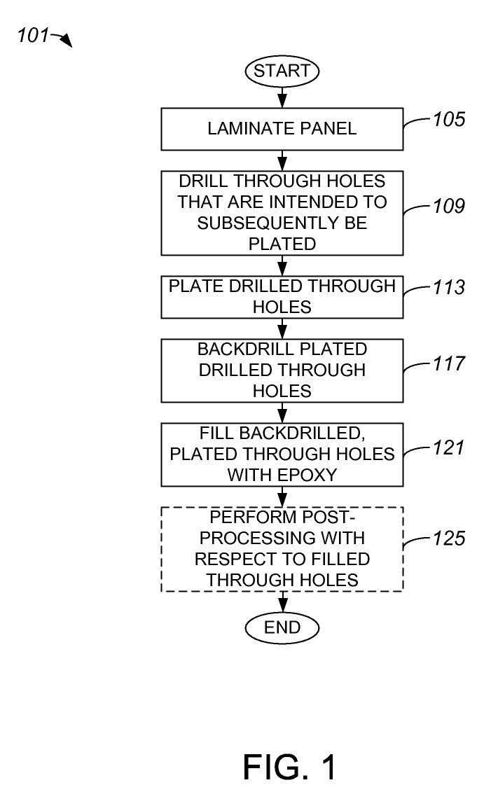

Referring initially to FIG. 1, one process of creating filled, backdrilled vias or plated through holes in a printed circuit board panel will be described in accordance with an embodiment of the present invention. A process of creating filled, backdrilled vias or through holes 101 begins at step 105 in which a printed circuit board panel is laminated. Substantially any suitable method may be used to laminate a panel. Upon laminating the panel, through holes or vias are drilled in the panel in step 109. Such through holes or vias generally include through holes which are intended to subsequently be plated. A drilling process may include, but is not limited to including, positioning the panel on a table of a drilling machine and then drilling through holes at desired locations. It should be appreciated that although a drilling process is typically used to form through holes, any process which is capable of forming through holes may be used.

The size of the through holes may vary, depending upon the requirements of a particular panel. For example, a through hole may be as small as approximately 7.8 milliinches (mils), or larger than approximately 40 mils. In one embodiment, through holes may be between approximately 9 mils in diameter and approximately 10 mils in diameter, e.g., approximately 9.8 mils in diameter. It should be appreciated, however, that a through hole may be substantially any size, and is not limited to the sizes mentioned above as suitable examples of through hole sizes. For ease of discussion, although through holes are described, it should be understood that descriptions relating to through holes generally also apply to vias.

Once the through holes are drilled, the drilled through holes are plated in step 113. That is, the surfaces or the barrels of the drilled through holes are plated. Typically, the drilled through holes may be plated using substantially any metallic material. In one embodiment, the drilled through holes are plated with a copper material.

After the drilled through holes are plated, portions of the plated, drilled through holes are backdrilled in step 117. Backdrilling a plated through hole effectively removes the plating from a portion of the through hole. Generally, in addition to removing the plating from a portion of the through hole, backdrilling also widens a circumference or increases the diameter of the portion of the through hole. By way of example, when a plated through hole which has a diameter of approximately 9.8 mils is backdrilled, the portion that is backdrilled may have a resultant diameter of between approximately 18 mils and approximately 20 mils.

In step 121, the backdrilled through holes are filled with a non-conductive material, e.g., an epoxy or a solder mask. Filling the backdrilled through holes with a non-conductive material allows relatively high density circuit routing to occur between the backdrilled through holes, as for example between high density pin areas and beneath BGAs. Substantially any suitable method may be used to fill the backdrilled through holes with a non-conductive material. For instance, a non-conductive material may effectively be injected into each through hole using a hole fill machine, rollers, and/or a vacuum.

Once the backdrilled through holes are substantially filled with a non-conductive material, post-processing may optionally be performed on the filled through holes in step 125. Post-processing may include, but is not limited to including, planarizing surfaces associated with the non-conductive material, and plating over top and/or bottom surfaces of the filled through hole. After any desired post-processing of the filled through holes is completed, the process of creating filled, backdrilled through holes is completed.

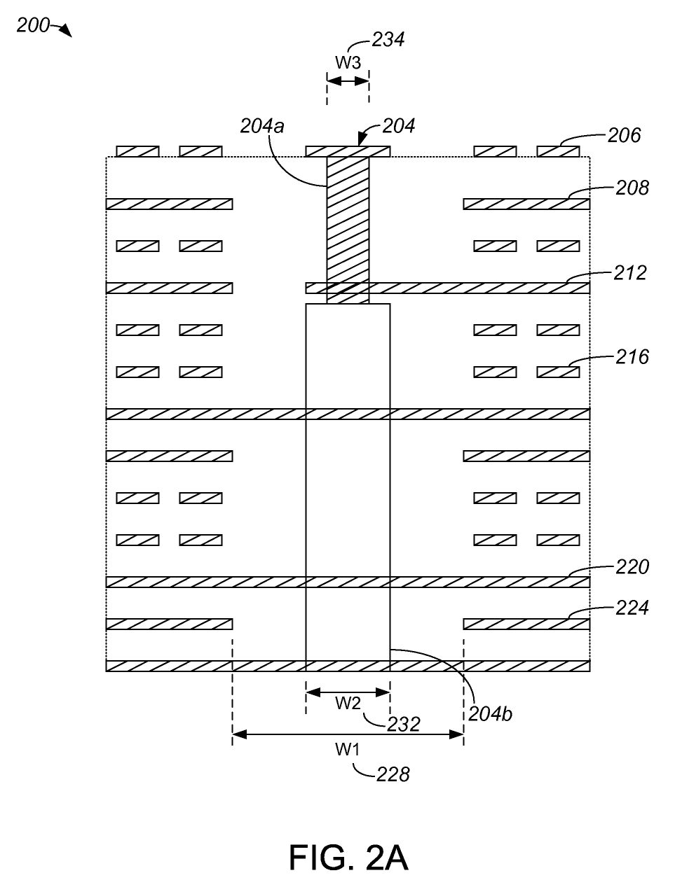

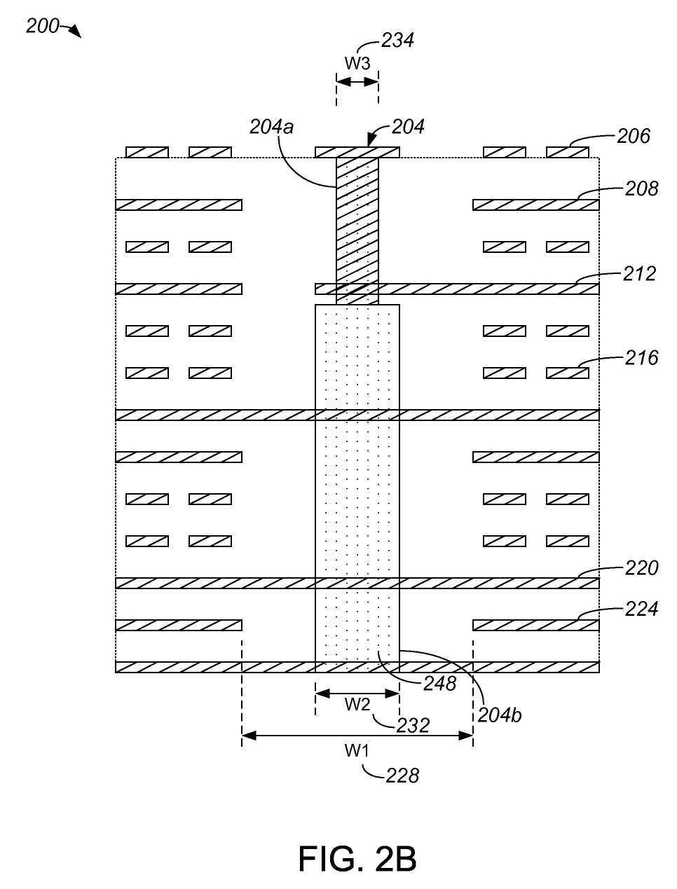

In general, a panel may include multiple layers through which a filled, backdrilled through hole may pass. FIG. 2A is a diagrammatic cross-sectional side-view representation of a panel in which a backdrilled via is formed that may subsequently be filled in accordance with an embodiment of the present invention. A panel 200, which may be a printed circuit board or a PWB, includes a hole arrangement 204. Hole arrangement 204, which may generally be a via or a plated through hole, includes a first portion 204a and a second portion 204b. First portion 204a is a plated portion, e.g., a plated barrel, and second portion 204b is an unplated portion, e.g., a backdrilled barrel.

A diameter W2 of second portion 204b is generally larger than a diameter W3 234 of first portion 204a. In one embodiment, diameter W2 is in the range between approximately 18 mils and approximately 20 mils, while diameter W3 234 may be approximately 9.8 mils.

Panel 200 generally includes multiple layers. The layers typically include a surface layer 206, at least one critical signal layer 212, at least one signal layer 216, and at least one ground plane 220, and at least one power plane 224. As will be appreciated by those skilled in the art, surface layer 206 may either be a signal layer, a plane layer, or a combination of a signal layer and a plane layer. Typically, for power planes such as power plane 224 and ground planes such as ground plane 220, a clearance area or an anti-pad with a diameter W1 228 is maintained about a centerline (not shown) of hole arrangement 204. In one embodiment, diameter W1 228 may be at least approximately 30 mils.

Critical signal layer 212 is arranged such that at least one trace or wire in critical signal layer 212 is communicably coupled to first portion 204a. Ground plane 220 does not include a pre-defined anti-pad, although it should be appreciated that a ground plane 208 within panel 200 may include a pre-defined anti-pad or a clearance area with a diameter W1 228, as previously mentioned.

As will be appreciated by those skilled in the art, a pre-defined anti-pad is a clearance area in a plane, e.g., a copper plane, through which hole arrangement 204 may be drilled or otherwise pass. Typically, the clearance area is associated with diameter WI 228. In the embodiment as shown, a pre-defined anti-pad associated with a ground layer 208 may enable first portion 204a to pass through ground layer 208 substantially without contacting copper associated with ground layer 208. In general, a pre-defined or standard anti-pad may have an area of approximately 700 square mils when diameter W3 234 is as small as approximately 9.8 mils and diameter W1 228 is approximately 30 mils.

Second portion 204b effectively creates a drill-defined anti-pad in critical signal layer 212. The diameter associated with such a drill defined anti-pad may vary widely, and may be in the range between approximately 18 mils and approximately 20 mils, thereby resulting in an area of between approximately 254 square mils and approximately 314 square mils.

Hole arrangement 204 may be filled with a non-conductive material such as epoxy. FIG. 2B is a diagrammatic cross-sectional side-view representation of panel 200 in which hole arrangement 204 is filled with a non-conductive material in accordance with an embodiment of the present invention. As shown, substantially all of hole arrangement 204 is filled with a non-conductive material 248.

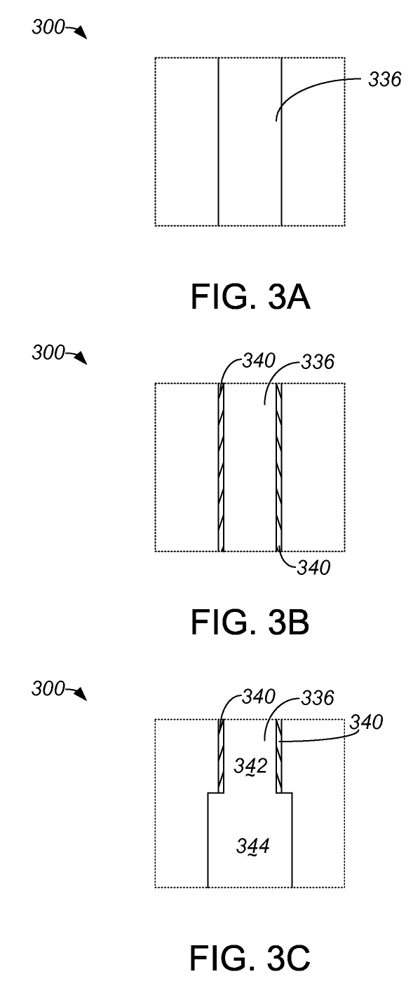

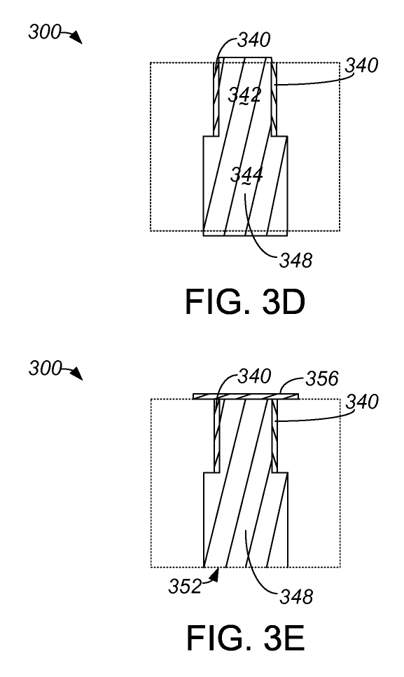

With reference to FIGS. 3A-3E, steps associated with the formation of filled, backdrilled plated through holes will be described in accordance with an embodiment of the present invention. FIG. 3A is a diagrammatic cross-sectional side view representation of a panel in which a through hole is formed in accordance with an embodiment of the present invention. A panel 300 such as a laminated printed circuit board is obtained, and a hole or an opening 336 is created therethrough. Hole 336 may be created using a drilling process, e.g., a drilling process that uses an approximately 9.8-mil drill bit. Creating hole 336 effectively creates surfaces that define a barrel of hole 336.

Once created, hole 336 may be plated with a metallic material. FIG. 3B is a diagrammatic cross-sectional side view representation of a panel 300 after hole 336 has been plated in accordance with an embodiment of the present invention. Plated layer 340 effectively covers the barrel of hole 336. Although plated layer 340 may be formed from copper, it should be appreciated that plated layer 340 may generally be formed from substantially any conductive or metallic layer.

A backdrilling process removes at least a portion of plated layer 340, and effectively increases the diameter of hole 340 with respect to that portion of hole 336. As shown in FIG. 3C, after backdrilling, hole 340 substantially includes a plated portion 342 and an unplated portion 344. Plated portion 342 generally has a smaller diameter than unplated portion 344, as backdrilling bores out material from panel 300 in addition to plating 340.

FIG. 3D is a diagrammatic cross-sectional side view representation of panel 300 after a filling process has occurred in accordance with an embodiment of the present invention. The filling process may be, in one embodiment, an epoxy filling process. In general, after backdrilling occurs, both plated portion 342 and unplated portion 344 of hole 336 may be filled with a non-conductive material 348, e.g., epoxy. As shown, an epoxy filling process may result in a need to planarize at least one surface associated with the epoxy. Planarizing the surface of the epoxy, as well as plating over the epoxy, may occur after the epoxy has cured or otherwise hardened. It should be appreciated that planarizing the surface of the epoxy and/or plating over the epoxy are optional processes.

FIG. 3E is a diagrammatic cross-sectional side view representation of panel 300 after a planarization process and an additional plating process have occurred in accordance with an embodiment of the present invention. As shown, an epoxy surface 352 has been planarized, e.g., using a sanding process, such that epoxy surface 352 is substantially even with a bottom surface of panel 300. Similarly, an epoxy surface may be substantially even with a top surface. A top plated layer 356 has been added to a top surface of panel 300 such that plated layer 340 is communicably coupled to top plated layer 356. In one embodiment, top plated layer 356 covers a top surface of epoxy 348. Although only top plated layer 356 is shown, it should be appreciated that a plated layer (not shown) may also be added over epoxy surface 352.

Although only a few embodiments of the present invention have been described, it should be understood that the present invention may be embodied in many other specific forms without departing from the spirit or the scope of the present invention. By way of example, while an entire backdrilled through hole has generally been described as being filled with epoxy, substantially only the backdrilled portion of the through hole may instead be filled with a non-conductive material such as epoxy. In other words, the plated portion of a through hole may not necessarily be filled with a non-conductive material.

While filled, backdrilled through holes have been described, cavities which are not effectively through holes may also be backdrilled and then filled. For instance, a plated hole which penetrates at least some but not all layers associated with a panel may be backdrilled and then filled. In one embodiment, a top portion of a plated cavity may be backdrilled to remove plating.

The present invention may be applied to a through hole or a via that is partially plated. By way of example, a through hole that includes a partially plated circumference may be filled with a non-conductive material.

A via or plated through hole has been described as being backdrilled from one side. It should be understood that a via or plated through hole may be backdrilled from two sides, e.g., from a top side and a bottom side, such that a plated portion remains substantially near the middle of a PWB or, more generally, a panel. In other words, a backdrilled and filled via and/or plated through hole may be formed such that the via and/or plated through hole includes two drilled out portions that substantially surround a plated portion.

The steps associated with the methods of the present invention may vary widely. Steps may be added, removed, altered, combined, and reordered without departing from the spirit of the scope of the present invention. Therefore, the present examples are to be considered as illustrative and not restrictive, and the invention is not to be limited to the details given herein, but may be modified within the scope of the appended claims.

What is claimed is:

1. A method comprising:
defining a hole in a printed circuit board panel, the hole being defined to have a first surface, wherein the hole includes at least a first portion and a second portion;
plating the first surface with a conductive material, wherein plating the first surface creates a plated surface;
removing at least a first area of the plated surface, the first area of the plated surface being associated with the second portion, wherein removing the at least first area of the plated surface includes expanding a size of the hole associated with the second portion; and
filling the hole with a non-conductive material.

2. The method of claim 1 wherein removing at least the first area of the plated surface includes backdrilling the hole.

3. The method of claim 1 wherein the non-conductive material is an epoxy.

4. The method of claim 1 wherein the conductive material is a metallic material.

5. The method of claim 1 further including:
planarizing a surface of the non-conductive material; and
plating at least a portion of the surface of the non-conductive material.

6. The method of claim 1 wherein defining the hole include drilling the hole.

7. The method of claim 6 wherein the hole is a through hole.

8. A system comprising:
means for defining a hole in a printed circuit board panel, the hole being defined to have a first surface, wherein the hole includes at least a first portion and a second portion;
means for plating the first surface with a conductive material, wherein the means for plating the first surface create a plated surface;
means for removing at least a first area of the plated surface, the first area of the plated surface being associated with the second portion, wherein the means for removing the at least first area of the plated surface include means for expanding a size of the hole associated with the second portion; and
means for filling the hole with a non-conductive material.

9. An apparatus comprising:
at least one trace; and
at least a first hole defined by a surface, the first hole being filled with a non-conductive material, the surface including a plated portion and an unplated portion, the unplated portion being arranged to be created by a backdrilling process, wherein the trace is communicably coupled to the plated portion of the surface.

10. The apparatus of claim 9 wherein the non-conductive material is epoxy.

11. The apparatus of claim 10 wherein the epoxy is in contact with the plated portion and the unplated portion.

12. The apparatus of claim 9 further including a plated area, the plated area being arranged over the non-conductive material.

13. The apparatus of claim 9 wherein the first hole is a through hole.

14. The apparatus of claim 9 wherein the apparatus is a printed circuit board.

15. The apparatus of claim 14 wherein the printed circuit board is a line card.

16. The apparatus of claim 9 including a plurality of trace layers, a first trace layer of the plurality of trace layers including the trace, wherein the first hole is arranged to traverse the plurality of trace layers.

17. The apparatus of claim 9 including a ground layer, the first hole being arranged to traverse the ground layer, wherein the unplated portion is arranged to substantially define an anti-pad in the ground layer.

18. The apparatus of claim 17 wherein the anti-pad has an area between approximately 200 square milliinches (mils) and approximately 350 square mils.

19. The apparatus of claim 18 wherein the anti-pad has an area of between approximately 254 square mils and approximately 314 mils.
